(19) United States
(12) Patent Application Publication
(10) Pub. No.: US 2007/0138375 A1
(43) Pub. Date: Jun. 21, 2007

(54) Image sensor, test system and test method for the same

(75) Inventors: Gidoo Lee, Suwonsi (KR); SeungJoon Cha, Seoul-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/638,516

(22) Filed: Dec. 14, 2006

(30) Foreign Application Priority Data
Dec. 19, 2005 (KR) 10-2005-0125480

(51) Int. Cl. H01J 40/14

(52) U.S. Cl. 250/214 R

(57) ABSTRACT

In one embodiment, the CMOS image sensor includes a plurality of pixels, and the plurality of pixels include active pixels and optical black pixels. At least one bias input structure is configured to receive a bias voltage and only supply the bias voltage to one or more of the optical black pixels. An output circuit is configured to generate an output signal based on output from the plurality of pixels.

### BACKGROUND OF THE INVENTION

1. Priority Statement

This application claims benefit of priority under 35 U.S.C. § 119 from Korean Patent Application No. 10-2005-0125480 filed on Dec. 19, 2005, in the Korean Patent Office, the disclosure of which is incorporated herein by reference in its entirety.

2. Field of the Invention

The present invention relates to CMOS image sensors, and test systems and methods therefore.

3. Description of Related Art

Semiconductor image sensing devices are widely used for capturing images in a variety of applications such as digital cameras, camcorders, printers, scanners, etc. The semiconductor image sensing devices include image sensors that capture optical information and convert the optical information into electrical signals. The electrical signals are processed, stored and otherwise manipulated to produce an image on a display or medium (e.g., print medium).

Two types of semiconductor image devices are currently in wide use: a charge coupled device (CCD) and a CMOS image sensor. A CMOS image sensor operates with lower power consumption than a CCD, and therefore, finds particularly applicability to portable electronic devices. A CMOS image sensor or sensing system typically includes a CIS unit and an image signal processing (ISP) unit. The CIS unit performs the function of converting optical information into electrical information, and the ISP unit performs the function of signal processing the electrical information. More particularly, the CIS unit includes an array of pixels formed by photocells and associated digital coding circuitry. Each photocell includes a photodiode to sense illumination, and convert optical information into an analog voltage level. The digital coding circuitry converts the analog voltage level into a corresponding digital code through correlated double sampling (CDS). The digital codes are supplied to the ISP unit, which performs the signal processing function on the received digital codes. The CIS unit and ISP unit may be on a single chip or on separate chips.

To prevent CMOS image sensors containing defects from entering the market place, the CMOS image sensors are typically tested. However, testing is not easy as it is difficult to control the intensity of light incident on the CIS unit. Typically, under test conditions it is desirable to change the intensity of light incident on the CIS unit in step increments. To do this requires a costly light source. Furthermore, testing is a time consuming process as the data from each pixel in the CIS unit is tested. The test unit may receive the output of the CIS unit, the ISP unit or both. However, the test generally involves testing the characteristics of each unit separately, and not the CMOS image sensor as a whole.

### SUMMARY OF THE INVENTION

The present invention relates to a CMOS image sensor.

One embodiment of the CMOS image sensor according to the present invention includes a plurality of pixels, and the plurality of pixels include active pixels and optical black pixels. At least one bias input structure is configured to receive a bias voltage and only supply the bias voltage to one or more of the optical black pixels. An output circuit is configured to generate an output signal based on output from the plurality of pixels.

In one embodiment, the bias input structure includes at least one bias pad receiving the bias voltage and supplying the bias voltage to one or more of the optical black pixels.

In another embodiment, the bias input structure includes at least one switch controlling the supply of the bias voltage from the bias pad to the one or more rows of the optical black pixels.

In yet another embodiment, the bias input structure includes at least a first switch and a second switch. Each of the first and second switches controls the supply of the bias voltage from the bias pad to a respective row of the optical black pixels.

With respect to the above described embodiments, a controller may control the operation of the switch or switches.

In one embodiment, each optical black pixel includes a photodiode, and a first transistor transferring a supply voltage as an output voltage based on output from the photodiode. And, the bias input structure supplies the bias voltage to the output of the photodiode.

In one embodiment, a CMOS image sensor unit includes the plurality of pixels, the bias input structure, and the output circuit. An image signal processing unit is configured to perform signal processing on output from the CMOS image sensor unit to generate an image signal.

The present invention further relates to a method of generating test data from a CMOS image sensor.

According to one embodiment of the method, the CMOS image sensor includes a plurality of pixels, and the plurality of pixels include active pixels and optical black pixels. In the method, a bias voltage is received, and the bias voltage is supplied to only one or more of the optical black pixels.

The present invention still further relates to a method of testing a CMOS image sensor.

According to one embodiment, a bias is applied to only optical black pixels of the CMOS image sensor, and test data, generated based on the applied bias, is received from the CMOS image sensor. At least one characteristic of the CMOS image sensor is determined based on the received test data.

Still further, the present invention relates to a testing device for testing a CMOS image sensor.

In one embodiment, the testing device includes a signal generator configured to apply a bias to only optical black pixels of the CMOS image sensor, and a test processor configured to receive test data, generated based on the applied bias, from the CMOS image sensor. The test processor is also configured to determine at least one characteristic of the CMOS image sensor based on the received test data.

### BRIEF DESCRIPTION OF THE DRAWINGS

The present invention will become more fully understood from the detailed description given herein below and the accompanying drawings, wherein like elements are represented by like reference numerals, which are given by way of illustration only and thus are not limiting of the present invention and wherein:

FIG. 1 illustrates an embodiment of a CMOS image sensor and tester according to the present invention;

FIG. 2 illustrates the CIS unit of the CMOS image sensor in FIG. 1 in greater detail;

FIGS. 3A and 3B illustrate different embodiments of the optical black pixel area in the pixel array of the CIS unit of FIG. 2;

FIG. 4 illustrates an example embodiment of an active pixel in the pixel array of FIG. 2;

FIG. 5 illustrates an example embodiment of an optical black pixel in the pixel array of FIG. 2;

FIG. 6 illustrates a waveform diagram of signals applied in and output from an the CIS unit of FIG. 2 during a test operation;

FIG. 7 illustrates an example embodiment of the tester shown in FIG. 1; and

FIGS. 8 and 9 illustrate other embodiments of a bias input structure according to the present invention.

### DETAILED DESCRIPTION OF EXAMPLE EMBODIMENTS

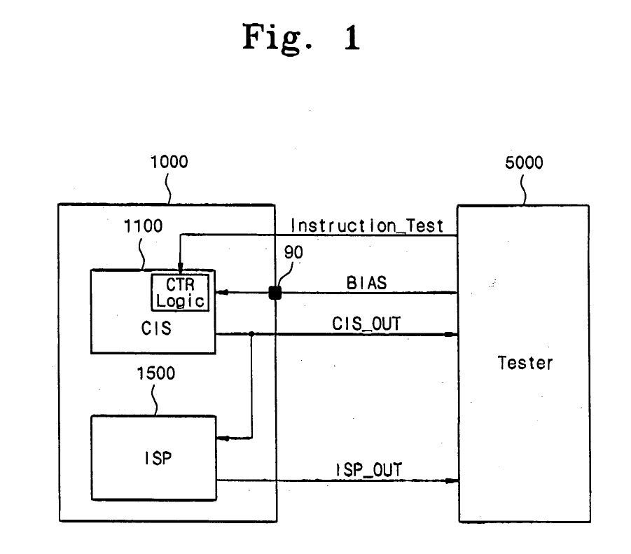

FIG. 1 illustrates an embodiment of a CMOS image sensor 1000 connected to a tester 5000 according to the present invention. As shown, the CMOS image sensor 1000 includes a CIS unit 1100 and an ISP unit 1500. The ISP unit 1500 receives the output CIS_OUT of the CIS unit 1100, and generates an output ISP_OUT. When connected to the CIS image system 1000, the tester 5000 receives the output CIS_OUT from the CIS unit 1100 and the output ISP_OUT from the ISP unit 1500.

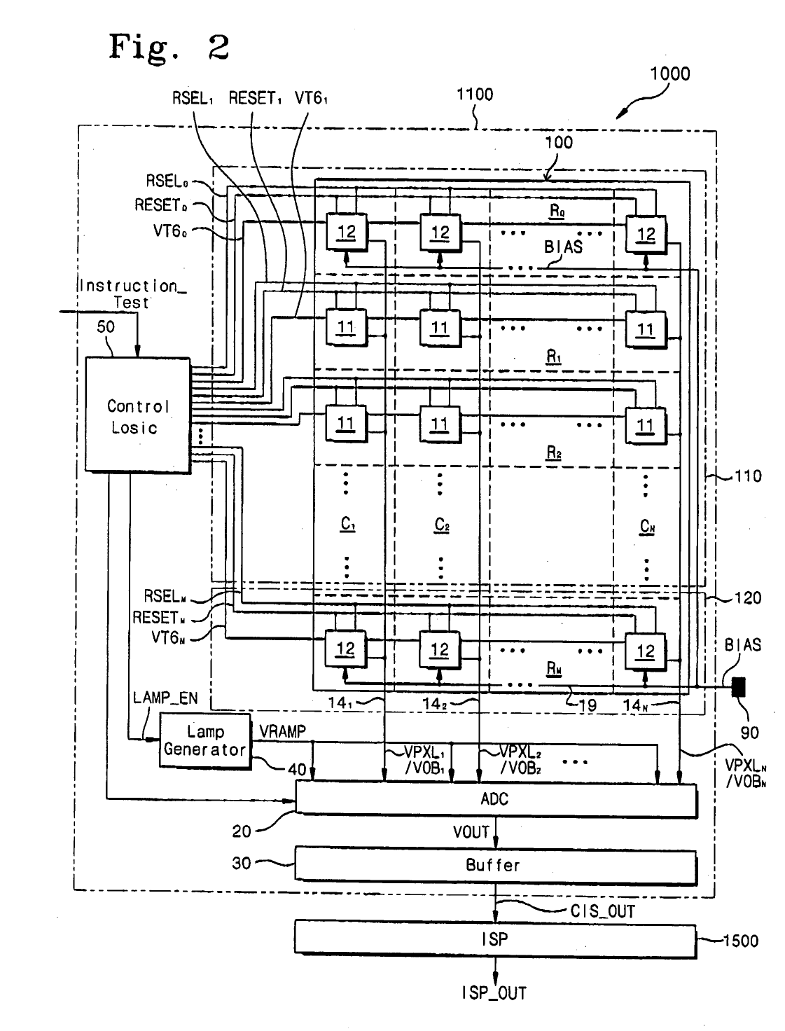

When connected, and during a test, the tester 5000 sends a test mode instruction INSTRUCTION_TEST to control logic 50 in the CIS unit 1100, and the tester 5000 supplies a bias BIAS to a test bias pad (or pads) 90 of the CIS unit 1100. The structure and operation of the CIS unit 1100 will be described in more detail below with respect to FIG. 2. The ISP unit 1500 may be any well-known image signal processing architecture and/or perform any well-known image signal processing. Accordingly, the ISP unit 1500 will not be described in detail for the sake of brevity.

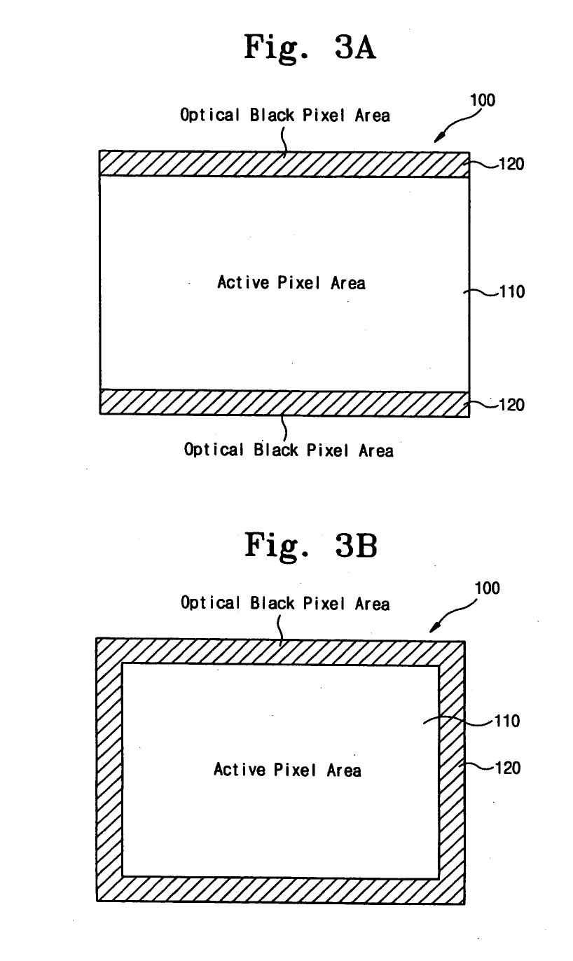

FIG. 2 illustrates the CIS unit 1100 of FIG. 1 in greater detail. As shown, the CIS unit 1100 includes a pixel array 100, and the pixel array 100 includes an active pixel area 110 and an optical black pixel area 120. As shown in FIG. 3A, in one embodiment, the optical black pixel area 120 may comprise the top and bottom peripheral areas of the pixel array 100. Alternatively, as shown in FIG. 3B, the optical black pixel area 120 may comprise the entire peripheral area of the pixel array 100. For the sake of example only, FIG. 2 illustrates the case where the optical black pixel area 120 comprises the top and bottom peripheral areas of the pixel array 100.

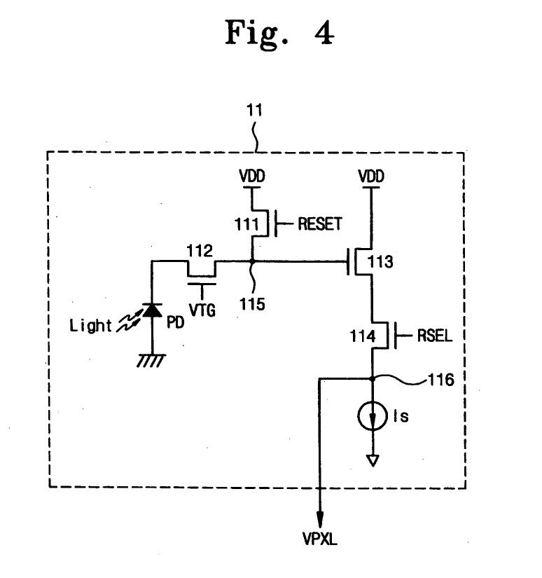

As shown in FIG. 2, the active pixel area 110 includes a plurality of rows of active pixels 11. The control logic 50 supplies each row of active pixels with a respective selection signal RSEL, reset signal RESET and transfer signal VTG. Each active pixel 1 has the same structure, and FIG. 4 illustrates an example embodiment of an active pixel 11. Each active pixel 11 may have the structure shown in FIG. 4. As shown, the active pixel 11 includes a photodiode PD connected between ground and a transfer transistor 112, which may be an NMOS transistor. The gate of the transfer transistor 112 receives the transfer signal VTG. A reset transistor 111 is connected between the transfer transistor 112 and a power supply voltage VDD. The reset transistor 111 may be an NMOS transistor, and receives the reset signal RESET at its gate.

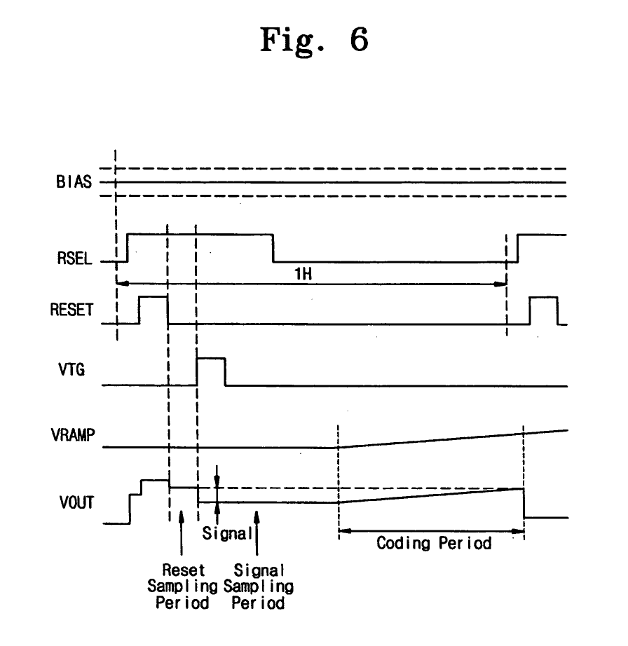

As further shown in FIG. 4, a source follower transistor 113, a selection transistor 114 and a current source Is are connected in series between the supply voltage VDD and a reference voltage (e.g., ground). The source follower transistor 113 and the selection transistor 114 may be NMOS transistors. The outputs of the transfer transistor 112 and the reset transistor 111 are connected to the gate of the source follower transistor 113. The gate of the selection transistor 114 receives the selection signal RSEL. The node between the selection transistor 114 and the constant current source Is serves as the output node 116 of the active pixel 11, and provides the output pixel voltage VPXL. The operation of the active pixel shown in FIG. 4 will be described in detail later with respect to FIG. 6.

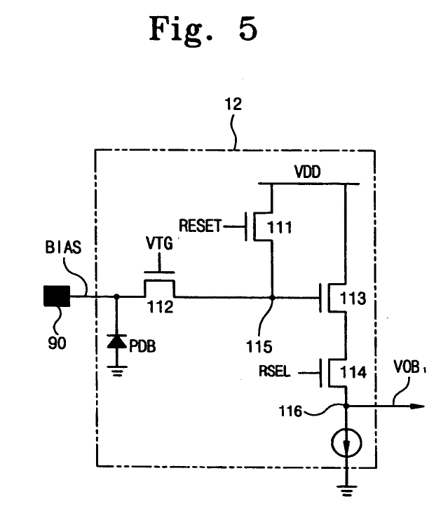

As shown in FIG. 2, each of the optical black pixel areas 120 includes a row of optical black pixels 12. However, it will be understood that more than one row of optical black pixels 12 may be included in an optical black pixel area 120. FIG. 5 illustrates the structure of an optical black pixel 12. Each of the optical black pixels 12 may have the same structure. As shown in FIG. 5, the structure of the optical black pixel 12 is the same as the structure of the active pixel 11 shown in FIG. 4, except that the photodiode PD in the active pixel 11 has been replaced with a blacked out photodiode PDB. The blacked out photodiode PDB is the same as the photodiode PD except that the light receiving surface of the photodiode PDB has been coated with an opaque material such as a metal blocking layer. As a result, the data from an optical black pixel 12 may ideally by zero; however, some value does exist due to some “dark current” existing in the CIS unit 1100. Namely, the silicon wafer in which the photodiodes PD and PDB are formed may include defects (e.g., dangling bonds), and these defects may result in “dark current”, which looks like white dots on the display even though the photodiodes PDB are optically blacked out. The output from the optical black pixels 12 is referred to as VOB to differentiate this output from the output VPXL of the active pixels 11.

During normal operation, the voltage representing the dark current read from the optical black pixels 12 is used to compensate the data read from the active pixels 11. With respect to embodiments of the present invention, the optical black pixels 12 are used to test the CMOS image sensor 1000. As shown in FIG. 5, according to one embodiment of the present invention, the optical black photodiodes PDB in the optical black pixels 12 are connected directly to the test bias pad 90.

Returning to FIG. 2, the control logic 50 provides the reset signals RESET, selection signals RSEL, and transfer signal VTG to the active and optical black pixels 11 and 12. The control logic 50 generates these signals during a normal operation mode such that an image is sampled by the active pixels 12. This operation is well-known, and is not the subject of this application. Accordingly, for the sake of brevity, this operation will not be described in great detail. The control logic 50 also generates these signals during a test operation such that the optical black pixels 12 generate output VOB for test purposes or dark current compensation purposes.

As will be understood by those skilled in the art, during normal operation, the control logic 50 generates the control signals based on various inputs (e.g., user input, a host system input, etc.). However, these inputs have not been shown for the sake of clarity. Instead, the test mode instruction INSTRUCTION_TEST input from the tester 5000 has only been illustrated.

When the test mode instruction INSTRUCTION_TEST indicates or triggers testing of the CMOS image sensor 1000, the control logic 50 does not select any of the active pixels; for example, sends logic low selection signals RSEL to the active pixels 11. Instead, the control logic 50 activates only the optical black pixels 12, as will be described in detail below with respect to FIG. 6. Also, as part of the normal or test operation, the control logic 50 also controls the generation of a ramp signal VRAMP output by a lamp generator 40. This will also be discussed in detail below with respect to FIG. 6.

As shown in FIG. 2, the outputs from the active pixels 11 and the optical black pixels 12 are received by an analog-to-digital converter 20. The analog-to-digital converter 20 converts the analog voltage signals output by the respect pixels 11 and 12 in the pixel array 100 into digital codes; for example, in the well-known correlated double sampling manner. Because the structure and operation to perform CDS is so well-known, the analog-to-digital converter 20 will not be described in detail.

A buffer 30 stores the digital codes output by the analog-to-digital converter 20, and supplies the digital codes to the ISP 1500 as the output CIS_OUT of the CIS unit 1100. As shown in FIG. 1, the tester 5000 receives this output CIS_OUT of the CIS unit 1100 during a test operation.

Next, the operation of the CIS unit 1100 during a test operation will be described with respect to FIG. 6. FIG. 6 illustrates a waveform diagram of signals applied in and output from an the CIS unit 1100 during a test operation. As shown, during a test operation, the tester 5000 applies a bias to the test bias pad 90. As shown in FIG. 5, this bias is applied to the optical black photodiode PDB in the optical black pixels 12. The tester 5000 also supplies the test mode instruction INSTRUCTION_TEST to the control logic 50 indicating to conduct a test operation. In response, the control logic 50 selectively activates the optical black pixels 12. As shown in FIG. 6, the testing of an optical black pixel 12 begins with a reset period during which the control logic 50 generates a logic low transfer signal VTG, a logic high selection signal RSEL and a logic high reset signal RESET. As a result, the reset transistor 113 and the selection transistor 114 turn on and the power supply voltage VDD is supplied as the output VOB of the optical black pixel 12. This is then reflected in the output VOUT from the analog-to-digital converter 20 as shown in FIG. 6.

While the selection signal remains logic high, the reset signal goes logic low. This is then followed by a sampling period, which begins with the control logic 50 sending a logic high sampling signal. This causes the transfer transistor 112 to turn on. As a result, the bias applied to the test bias pad 90 is connected via the transfer transistor 112 and the selection transistor 114 to the output node 116 of the optical black pixel 12. The applied bias simulates the application of a specific light intensity on the photodiode PDB if the photodiode PDB was the photodiode PD of an active pixel and not coated with a light blocking material. As will be appreciated, the greater the simulated light intensity, the lower the output voltage VOB from the optical black pixel PDB. For the bias shown in FIG. 6, the output from the analog-to-digital converter 20 changes as shown in FIG. 6.

Next, during a coding period in which the analog-to-digital converter 20 converts the output VOB of the optical black pixel into a digital code, the control logic 50 controls the lamp generator 40 to output a ramp voltage signal VRAMP. As shown in FIG. 6, the ramp voltage signal 40 slowly increases in voltage (i.e., ramps up). The analog-to-digital converter 20 generates the digital code using the ramp voltage signal as a reference voltage in the well-known CDS method to convert the analog voltage VOB into a digital code voltage VOUT.

As will be appreciated, the active pixels 11 operate in the same manner, except that the voltage generated by the photodiode PB as opposed to the bias is sampled by the transfer transistor 112.

As shown in FIG. 2, the digital code is buffered and then output as the output CIS_OUT of the CIS unit 1100. The tester 5000 receives the output CIS_OUT of the CIS unit 1100 and performs testing of the characteristics (e.g., performance) of the CIS unit 1100 in any well-known manner. Also, the output CIS_OUT of the CIS unit 1100 is supplied to the ISP unit 1500. Based thereon, the ISP unit 1500 generates an output ISP_OUT, which is also supplied to the tester 5000. Using the output CIS_OUT of the CIS unit 1100 and the output ISP_OUT of the ISP unit 1500, the tester 5000 may test characteristics (e.g., performance) of the ISP unit 1500 in any well-known manner. Still further, using the bias applied to the test bias pad 90 and the output ISP_OUT from the ISP unit 1500, the tester 5000 may test the characteristics (e.g., performance) of the CMOS image sensor as a whole in any well-known manner.

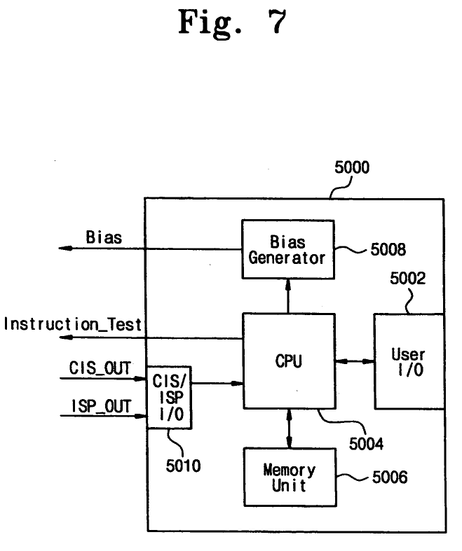

FIG. 7 illustrates an example embodiment of the tester 5000. As shown, the tester 5000 includes a user interface 5002 that receives user input regarding performing a test on a CMOS image sensor. Those instructions/requests are interfaced to a processor 5004, which executes the instruction/request pursuant to a testing program stored in a memory unit 5006. The memory unit 5006 may include a ROM, RAM, and/or etc.

As part of the testing program, the processor 5004 controls a bias generator 5008 to output the bias voltage BIAS. As will be appreciated, as part of the testing operation, the processor 5002 may cause the bias generator 5008 to step-wise (increment or decrement) change the generated bias voltage BIAS to simulate the application of different light intensities to the optical black pixels 12.

A CIS/ISP interface 5010 receives the outputs CIS_OUT and ISP_OUT from the CIS unit 1100 and the ISP unit 1500, respectively. The CIS/ISP interface 5010 supplies this data to the processor 5004. The processor 5004 may stored this data in the memory unit 5006, and perform the testing methodology on the stored data. The test results may then be provided to the user by the processor 5004 via the user interface 5002. As stated previously, the testing methodology may be any well-known testing methodology for testing the characteristics of the CIS unit 1100, the ISP unit 1500, and/or the CMOS image sensor 1000.

As will be appreciated from the disclosure, during a test operation, the bias (and therefore the testing) is only performed with respect to the optical black pixels 12. As such the testing is far less complex and time consuming than testing the entire pixel array.

As shown in FIG. 2, the bias input structure is the direct connection of the optical black photodiodes PDB to the test bias pad 90. And, as mentioned above, more than one test bias pad 90 may be provided to reduce the number of optical black pixels 12 connected to a single test bias pad 90. In one embodiment, for example, each optical black pixel 12 or each row of optical black pixels 12 may have its own test bias pad 90.

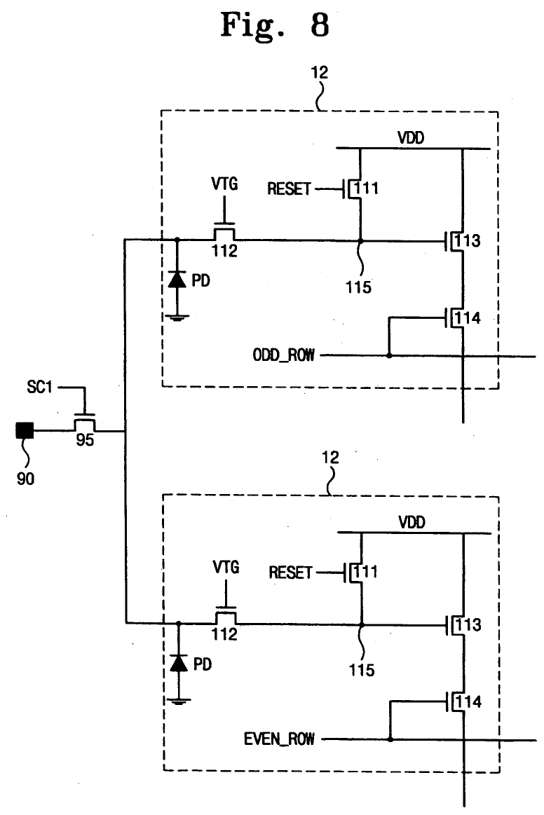

FIG. 8 illustrates another embodiment of a bias input structure according to the present invention. As shown, in this embodiment, a switch 95 is disposed between the test bias pad 90 and the rows of the optical black pixels 12. In this embodiment, the switch 95 is an NMOS transistor, and the gate of the transistor receives a switch control signal SC1 from the control logic 50. In this embodiment, the control logic 50 may control whether the bias applied to the test bias pad 90 reaches the optical black pixels 12 or not.

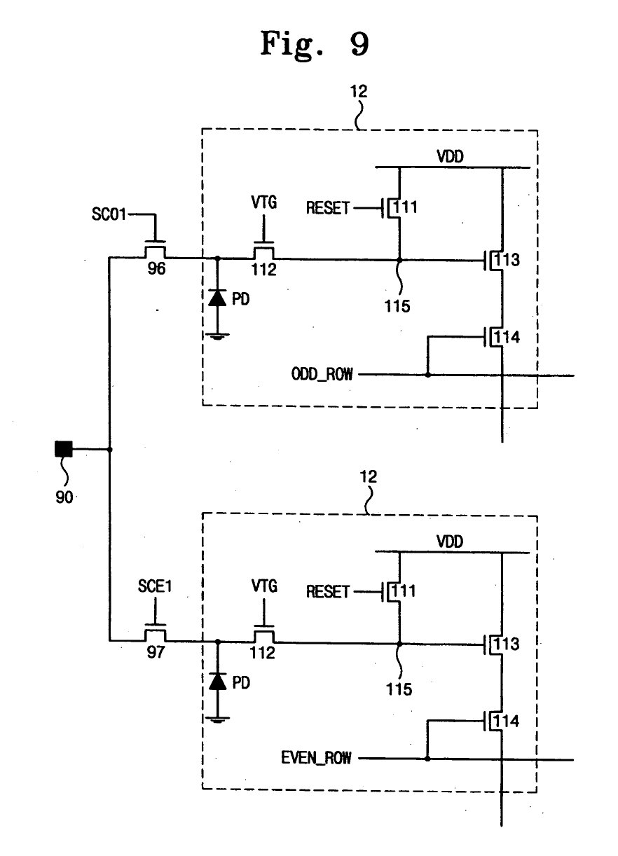

Furthermore, instead of a single switch for all of the optical black pixels 12, a switch may be provided in associated with each row of optical black pixels 90. For example, FIG. 9 illustrates an embodiment where an odd switch 96 is disposed between the test bias pad 90 and an odd row of optical black pixels 12, and an even switch 97 is disposed between the test bias pad 90 and an even row of optical black pixels 12. The odd switch 96 may be an NMOS transistor and receive an odd switch control signal SCO1 at its gate, and the even switch 97 may be an NMOS transistor and receive an even switch control signal SCE1 at its gate. The control logic 50 supplies the odd switch control signal SCO1 and the even switch control signal SCE1. In this embodiment, the control logic 50 may control whether the bias applied to the test bias pad 90 reaches an odd row of the optical black pixels 12 independently of whether the bias reaches an even row of optical black pixels 90, and vice versa.

Furthermore, each odd row of optical black pixels 12 may be connected to the odd switch 96 and each even row of optical black pixels 12 may be connected to the even switch 97. Alternatively, each odd row may be connected via a respective odd switch to the test bias pad 90, and each even row may be connected via a respective even switch to the test bias pad 90. Still further, different test bias pads may be provided for the even and odd rows.

The invention being thus described, it will be obvious that the same may be varied in many ways. Such variations are not to be regarded as a departure from the spirit and scope of the invention, and all such modifications as would be obvious to one skilled in the art are intended to be included within the scope of the present invention.

I claim:

1. A CMOS image sensor, comprising:
a plurality of pixels, the plurality of pixels including active pixels and optical black pixels;
at least one bias input structure configured to receive a bias voltage and only supply the bias voltage to one or more of the optical black pixels; and
an output circuit configured to generate an output signal based on output from the plurality of pixels.

2. The sensor of claim 1, wherein the bias input structure includes at least one bias pad receiving the bias voltage and supplying the bias voltage to one or more of the optical black pixels.

3. The sensor of claim 1, wherein the bias input structure includes at least one bias pad receiving the bias voltage and supplying the bias voltage to one or more rows of the optical black pixels.

4. The sensor of claim 3, wherein the bias input structure includes at least one switch controlling the supply of the bias voltage from the bias pad to the one or more rows of the optical black pixels.

5. The sensor of claim 4, further comprising:
a controller controlling operation of the switch.

6. The sensor of claim 4, wherein the bias input structure includes the switch controlling the supply of the bias voltage from the bias pad to more than one row of the optical black pixels.

7. The sensor of claim 6, further comprising:
a controller controlling operation of the switch.

8. The sensor of claim 4, wherein the bias input structure includes at least a first switch and a second switch, each of the first and second switches controlling the supply of the bias voltage from the bias pad to a respective row of the optical black pixels.

9. The sensor of claim 8, further comprising:
a controller controlling operation of the first and second switches.

10. The sensor of claim 8, wherein the first switch controls the supply of the bias voltage from the bias pad to an odd row of the optical black pixels, and the second switch controls the supply of the bias voltage from the bias pad to an even row of the optical black pixels.

11. The sensor of claim 1, wherein each optical black pixel comprises:
a photodiode;
a first transistor transferring a supply voltage as an output voltage based on output from the photodiode.

12. The sensor of claim 11, wherein the bias input structure supplies the bias voltage to the output of the photodiode.

13. The sensor of claim 11, wherein the bias input structure supplies the bias voltage to a gate of the first transistor.

14. The sensor of claim 11, wherein each optical black pixel further comprises:
a second transistor connected between the output of the photodiode and a gate of the first transistor.

15. The sensor of claim 14, wherein the bias input structure supplies the bias voltage to the output of the photodiode.

16. The sensor of claim 14, wherein the bias input structure supplies the bias voltage to a gate of the first transistor.

17. The sensor of claim 1, further comprising:
a CMOS image sensor unit, the CMOS image sensor unit including the plurality of pixels, the bias input structure, and the output circuit; and
an image signal processing unit configured to perform signal processing on output from the CMOS image sensor unit to generate an image signal.

18. A method of generating test data from a CMOS image sensor that includes a plurality of pixels, the plurality of pixels including active pixels and optical black pixels, and the method comprising:
receiving a bias voltage; and
supplying the bias voltage to only one or more of the optical black pixels.

19. A method of testing a CMOS image sensor, comprising:
applying a bias to only optical black pixels of the CMOS image sensor;
receiving test data, generated based on the applied bias, from the CMOS image sensor; and
determining at least one characteristic of the CMOS image sensor based on the received test data.

20. A testing device for testing a CMOS image sensor, comprising:
a signal generator configured to apply a bias to only optical black pixels of the CMOS image sensor; and
a test processor configured to receive test data, generated based on the applied bias, from the CMOS image sensor, and configured to determine at least one characteristic of the CMOS image sensor based on the received test data.
